(19) United States
(12) Patent Application Publication
(10) Pub. No.: US 2025/0212637 A1
(43) Pub. Date: Jun. 26, 2025

(54) SEMICONDUCTOR DEVICE, DISPLAY DEVICE, PHOTOELECTRIC CONVERSION DEVICE, AND ELECTRONIC DEVICE

(71) Applicant: CANON KABUSHIKI KAISHA, Tokyo (JP)

(72) Inventor: KAZUYA NOTSU, Kanagawa (JP)

(21) Appl. No.: 18/979,789

(22) Filed: Dec. 13, 2024

(30) Foreign Application Priority Data
Dec. 25, 2023 (JP) 2023-217768

(51) Int. Cl. H10K 59/131; H10K 59/88

(52) U.S. Cl. CPC H10K 59/131; H10K 59/88

(57) ABSTRACT

A semiconductor device according to the present invention includes: a semiconductor substrate; and a semiconductor chip connected to the semiconductor substrate via a plurality of terminals, wherein the semiconductor substrate includes an effective element area and a peripheral area surrounding the effective element area, the peripheral area is provided with an electrode portion to which the semiconductor chip is electrically joined, a plurality of rows of terminals are disposed along a first direction of the semiconductor chip, and terminals provided on a central portion of the semiconductor chip in the first direction, among the plurality of rows of terminals, are dummy terminals.

### BACKGROUND OF THE INVENTION

### Field of the Invention

The present invention relates to a semiconductor device, a display device, a photoelectric conversion device, and an electronic device.

### Description of the Related Art

In electronic devices, miniaturization, weight reduction, and high performance are required, and the number of external output terminals is rapidly increasing. With respect to the increase in the number of external output terminals, in the conventional wire bonding connection, there is a limit to narrowing the pitch of the connection terminals, and the electronic devices become large. Therefore, a technique of flip-chip mounting semiconductor chips has attracted attention. In the flip-chip mounting, since the bonding pads miniaturized by the semiconductor process can be connected to each other via a connection portion such as a bump, it is possible to significantly narrow the pitch of the external output terminals as compared with the conventional wire bonding connection. Examples of a bonding method of flip-chip mounting include ultrasonic bonding and solder bonding. In the manufacture of a display device such as an organic EL, a bonding method using an anisotropic conductive film (ACF) that can be bonded at a low temperature is generally used in order to suppress deterioration of an element due to heat in a bonding step.

In a display device, for example, a terminal of a semiconductor chip is flip-chip mounted on an electrode of a semiconductor substrate, but an electrical connection failure (disconnection, high electric resistance, or the like) may occur between the electrode of the semiconductor substrate and the terminal of the semiconductor chip.

An ACF is a film in which conductive particles are dispersed in a thermosetting resin. In a bonding method using an ACF as a bonding member, heat and pressure are applied to a member in which the ACF is disposed between an electrode and a terminal, so that conductive particles are sandwiched between the electrode and the terminal, and at the same time, thermal curing of the thermosetting resin proceeds. As a result, electrical connection between the electrode and the terminal is obtained. More specifically, the thermosetting resin crushed by heat and pressure is extruded to the outside of the semiconductor chip, so that the thickness of the thermosetting resin is reduced, and the conductive particles are sandwiched between the electrode and the terminal. As a result, electrical connection between the electrode and the terminal is obtained.

However, in the case of a terminal array in which a plurality of rows of terminal groups each having a short distance between terminals are disposed in the longitudinal direction of the semiconductor chip (and an electrode array corresponding to the terminal array), since the distance between the terminals is narrow, fluidity of the thermosetting resin in the longitudinal direction is poor. Therefore, the thermosetting resin is likely to remain in the central portion of the semiconductor chip, the thickness of the thermosetting resin is unlikely to be reduced even when heat and pressure are applied, and electrical connection failure between the electrode and the terminal is likely to occur. Since the thermosetting resin has poor fluidity in the longitudinal direction, the thermosetting resin needs to be extruded in the lateral direction, but in the case of a semiconductor chip elongated in the lateral direction, it is also difficult to extrude the thermosetting resin in the lateral direction. Therefore, in the case of a semiconductor chip elongated in the lateral direction, an electrical connection failure between the electrode and the terminal is particularly likely to occur.

In ultrasonic bonding, a thermosetting film such as an adhesive such as an epoxy resin or an acrylic resin or a non-conductive adhesive film (NCF) may be used to improve bonding strength and reliability. In this case, similarly to the case of the bonding using the ACF, the fluidity of the resin is poor at the central portion of the semiconductor chip, and the electrical connection failure between the electrode and the terminal is likely to occur.

In the technique disclosed in JP 2016-127259 A, a dummy bump is disposed between two bump groups. In the technique disclosed in JP 2005-26682 A, dummy bumps are disposed so as to be distributed at the four corners of a drive IC.

In flip-chip mounting using an ACF, a load is applied and heating is performed by upper and lower heaters with the ACF interposed between a semiconductor substrate and a semiconductor chip. However, in the central portion in the longitudinal direction of the semiconductor chip, the ACF resin is less likely to be discharged to the outside as compared with the outer peripheral portion, and the compression of charged particles between the electrode and the terminal becomes insufficient. As a result, there is a problem in that electric resistance increases. In both the techniques described in JP 2016-127259 A and JP 2005-26682 A, there is an electrical connection terminal in the central portion in the longitudinal direction of the semiconductor chip, and the deterioration of the electric resistance in the central portion of the semiconductor chip is not mentioned.

### SUMMARY OF THE INVENTION

The present invention has been made in view of the above problems, and provides a technique advantageous for stabilizing electric resistance at the time of connecting a semiconductor substrate and a semiconductor chip.

A semiconductor device according to the present invention provides a semiconductor device including: a semiconductor substrate; and a semiconductor chip connected to the semiconductor substrate via a plurality of terminals, wherein the semiconductor substrate includes an effective element area and a peripheral area surrounding the effective element area, the peripheral area is provided with an electrode portion to which the semiconductor chip is electrically joined, a plurality of rows of terminals are disposed along a first direction of the semiconductor chip, and terminals provided on a central portion of the semiconductor chip in the first direction, among the plurality of rows of terminals, are dummy terminals.

Further features of the present invention will become apparent from the following description of exemplary embodiments with reference to the attached drawings.

### BRIEF DESCRIPTION OF THE DRAWINGS

FIG. 1 is a plan view (schematic diagram) of a semiconductor device according to a first embodiment;

FIG. 2 is a terminal arrangement diagram (schematic diagram) of the semiconductor chip according to the first embodiment;

FIG. 3 is a schematic diagram illustrating a display device according to a second embodiment;

FIG. 4A is a schematic diagram illustrating an imaging apparatus according to the second embodiment;

FIG. 4B is a schematic diagram illustrating an electronic device according to the second embodiment;

FIGS. 5A and 5B are schematic diagrams illustrating display devices according to the second embodiment;

FIG. 6A is a schematic diagram illustrating an illumination device and a moving body according to the second embodiment;

FIG. 6B is a schematic diagram illustrating a moving body according to the second embodiment; and

FIGS. 7A and 7B are schematic diagrams illustrating wearable devices according to the second embodiment.

### DESCRIPTION OF THE EMBODIMENTS

Embodiments of the present invention will be described with reference to the accompanying drawings. Note that, in the following description and drawings, common components are denoted by common reference numerals throughout the plurality of drawings. Therefore, common configurations will be described with reference to a plurality of drawings, and description of configurations denoted by common reference numerals will be appropriately omitted.

### First Embodiment

A first embodiment will be described.

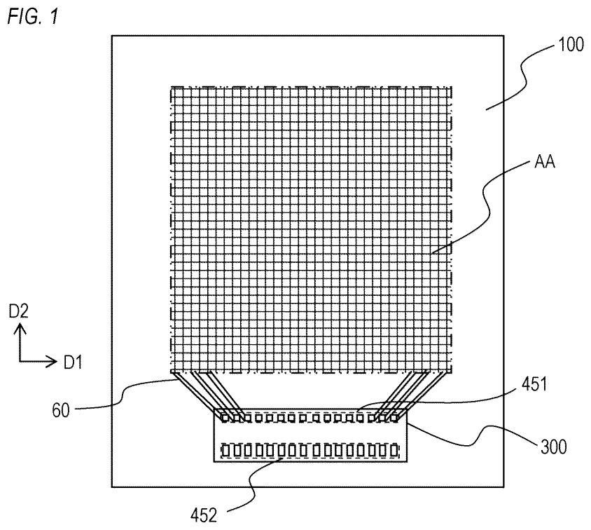

FIG. 1 is a plan view (schematic diagram) of a semiconductor device of a first embodiment in plan view. The arrangement in plan view is an arrangement when the semiconductor device is viewed from a direction perpendicular to the main surface of a semiconductor substrate 100 (normal direction of the main surface). The semiconductor substrate 100 includes an effective element area AA in which a functional element (not illustrated) is provided on a substrate such as silicon and a peripheral area located around the effective element area AA. In the peripheral area, an electrode portion (not illustrated) is provided, and the electrode portion and a semiconductor chip 300 are electrically connected. The effective element area AA is electrically joined to the electrode portion by wiring 60. The semiconductor chip 300 is a semiconductor chip provided with a drive circuit, and terminal groups (451 and 452) in which a plurality of terminals are disposed along a longitudinal direction (direction D1 in FIG. 1: first direction) of the semiconductor chip are disposed on a surface connected to the semiconductor substrate 100. The terminal is, for example, a gold or copper bump formed by plating, or a solder bump formed by mounting and reflowing a solder ball.

Each of the terminal groups (451 and 452) constitutes an output terminal group or an input terminal group. For example, each terminal of the terminal group 451 can be an output terminal and each terminal of the terminal group 452 can be an input terminal, or each terminal of the terminal group 451 can be an input terminal and each terminal of the terminal group 452 can be an output terminal. A terminal group constituted by a pair of input terminals and output terminals arranged in the lateral direction (direction D2 in FIG. 1: second direction) of the semiconductor chip is referred to as an input/output terminal group. The input/output terminal group includes one or a plurality of input terminals and one or a plurality of output terminals. A plurality of rows of input/output terminal groups are arranged along the first direction of the semiconductor chip, and each of the input/output terminal groups is electrically connected to the semiconductor substrate as an external connection terminal (external connection terminal group).

In general, the number of output terminals is large, and a desired number of output terminals is disposed by reducing the size of the output terminals or increasing the number of rows of the output terminals in the lateral direction of the semiconductor chip. In general, when about 2,000 to 10,000 output terminals are disposed, the length of one side of the output terminal is about 10 μm to 100 μm, and the height of the output terminal is about 3 μm to 50 μm. The interval between the output terminals is about 10 μm to 100 μm, and the number of rows of the output terminals is about 3 to 20. The electrode portion (not illustrated) includes a plurality of electrodes to which a plurality of output terminals are connected via a connection member.

In general, the number of input terminals is smaller than the number of output terminals, and the input terminal is required to have low electrical resistance. Therefore, the size of the input terminal is preferably large. In general, when about 300 to 2,000 input terminals are disposed, the length of one side of the input terminal is about 10 μm to 200 μm, and the width of the input terminal is about 3 μm to 50 μm. The interval between the input terminals is about 10 μm to 50 μm, and the number of rows of the input terminals in the lateral direction of the semiconductor chip (direction D2 in FIG. 1: second direction) is about 1 to 5. The electrode portion includes a plurality of electrodes to which a plurality of input terminals are connected via a connection member.

A functional elements (not illustrated) can be provided in the effective element area AA of the semiconductor substrate 100. The functional element is a display element, a photoelectric conversion element, or the like. In the case of a display element, the functional element is an EL element in an electroluminescence display (ELD), a liquid crystal element in a liquid crystal display (LCD), or a reflective element in a digital mirror device (DMD).

The peripheral area may include a peripheral circuit area (not illustrated) in which a peripheral circuit is disposed. For example, in the case of a display device, the peripheral circuit includes a drive circuit for driving effective pixels, a processing circuit (for example, a digital-analog conversion circuit (DAC)) for processing signals input to the effective pixels, and the like. The peripheral area may include a non-effective element area (not illustrated) located outside the effective element area AA and provided with a non-effective element. The non-effective element is an element that does not function as an effective element, and is a dummy element, a reference element, a test element, a monitor element, or the like.

The semiconductor substrate 100 and the semiconductor chip 300 can be bonded by flip chip bonding. Examples of the bonding member include an anisotropic conductive film (ACF), an NCF, an epoxy resin, and an acrylic resin. For example, the electrode of the semiconductor substrate 100 and the terminal of the semiconductor chip 300 are electrically connected by thermocompression bonding or ultrasonic compression bonding. ACF is a film in which conductive particles are dispersed in a thermosetting resin, and can be interpreted as an anisotropic conductive resin. As the thermosetting resin, an epoxy resin, an acrylic resin, or the like is used. The size and number of the conductive particles are selected according to the size of the terminal. For example, in a general ACF, the size (diameter) of the conductive particles is about 1 μm to 50 μm, and the number (area density) of the conductive particles is about 10,000˜100,000 particles/mm². By using the NCF, the epoxy resin, or the acrylic resin, the connection strength and reliability between the electrode and the terminal can be improved.

Since the connection member (ACF resin in the first embodiment) is less likely to be discharged to the outside in the central portion in the longitudinal direction of the semiconductor chip than in the outer peripheral portion, the charged particles are insufficiently compressed in the terminal located in the central portion, and the electrical resistance increases. In the semiconductor chip according to the first embodiment, a plurality of rows of input/output terminal groups are disposed along the first direction, and a dummy terminal group is provided as the input/output terminal group at the central portion of the semiconductor chip in the first direction. This can suppress an increase in electric resistance of the input/output terminal.

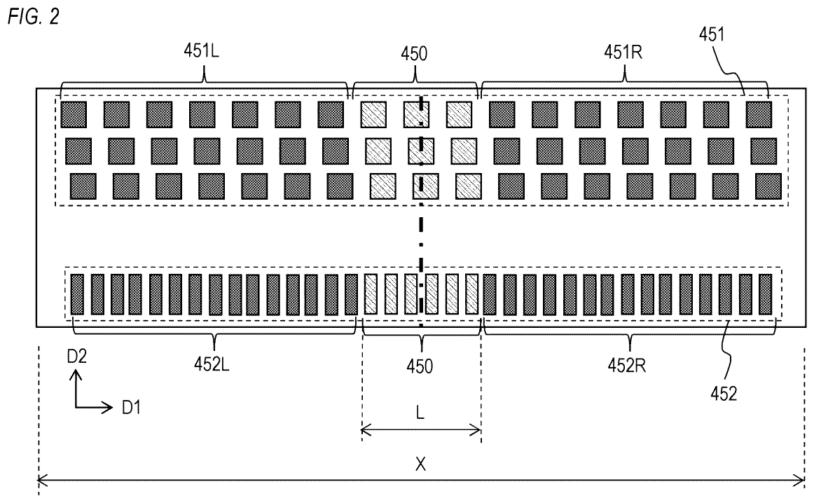

FIG. 2 is a terminal arrangement diagram (schematic diagram) of the semiconductor chip of the first embodiment, and is a perspective view (see-through view of a member overlapped with another member) of the semiconductor chip as viewed from the normal direction of the main surface of the semiconductor device. The first terminal group 451 is disposed along the longitudinal direction (direction D1 in FIG. 2) of the semiconductor chip, and an output terminal group (or an input terminal group) at the central portion in the longitudinal direction is set as a dummy terminal group 450. Both a first terminal group 451L disposed on the left side of the dummy terminal group 450 and a first terminal group 451R disposed on the right side of the dummy terminal group 450 function as an output terminal group (or an input terminal group). Similarly to the first terminal group 451, the second terminal group 452 is also disposed along the longitudinal direction (direction D1 in FIG. 2) of the semiconductor chip, and an input terminal group (or an output terminal group) at the central portion in the longitudinal direction is set as the dummy terminal group 450. Both a second terminal group 452L disposed on the left side of the dummy terminal group 450 and a second terminal group 452R disposed on the right side of the dummy terminal group 450 function as an input terminal group (or an output terminal group).

Each dummy terminal in the dummy terminal group may be provided in a pattern (shape, size) different from each terminal in the input/output terminal group, but is preferably provided in the same pattern. For example, when the terminal is formed by plating, the dummy terminal has the same pattern as that of the input/output terminal, so that the growth rate due to the difference in local current density and ion concentration during plating can be reduced. As a result, variations in terminal height can be suppressed, uniformity of a bonding load applied to each terminal can be improved, and bonding quality can be improved.

An interval (pitch) between the dummy terminal groups (dummy terminal groups instead of the input/output terminal groups) disposed in the lateral direction of the semiconductor chip is preferably wider than an interval between the input/output terminal groups disposed in the lateral direction of the semiconductor chip. By widening the interval (pitch) between the dummy terminal groups, the ACF resin is easily discharged to the outside of the semiconductor chip at the time of thermocompression bonding, and as a result, the film thickness uniformity of the ACF resin on the entire surface of the semiconductor chip is improved, and the distribution of the electric resistance can be made uniform.

In FIG. 2, the width of the semiconductor chip in the first direction is denoted by X, and the width of the area occupied by the dummy terminal group is denoted by L. Since the fluidity of the ACF resin varies depending on the melt viscosity, the curing speed, and the like of the ACF resin when heat and a load are applied in the compression step, a width L of the area occupied by the dummy terminal group can be appropriately adjusted depending on the type of the ACF resin and the compression conditions, and for example, L≥X/10. On the other hand, if the width of the area occupied by the dummy terminal group is arranged to be wide, the area where the first terminal group 451 and the second terminal group 452 are disposed becomes narrow, and thus it is preferable to satisfy L≤X/4. Specifically, when the width of the semiconductor chip is 20 mm, the width L of the area occupied by the dummy terminal group can be 2 mm or more and 5 mm or less.

As described above, by using the semiconductor device according to the first embodiment, it is possible to suppress an increase in electric resistance of the input/output terminal and to improve the yield of the semiconductor device.

### Second Embodiment

In a second embodiment, an example in which the semiconductor device according to the first embodiment is applied to various devices will be described. In a case where the semiconductor device is used in a display device, the semiconductor substrate 100 is a display element substrate, and a light emitting element is disposed in the effective element area AA. Furthermore, in a case where the semiconductor device is used in an imaging apparatus, the semiconductor substrate 100 is an imaging element substrate, and an imaging element is disposed in the effective element area AA.

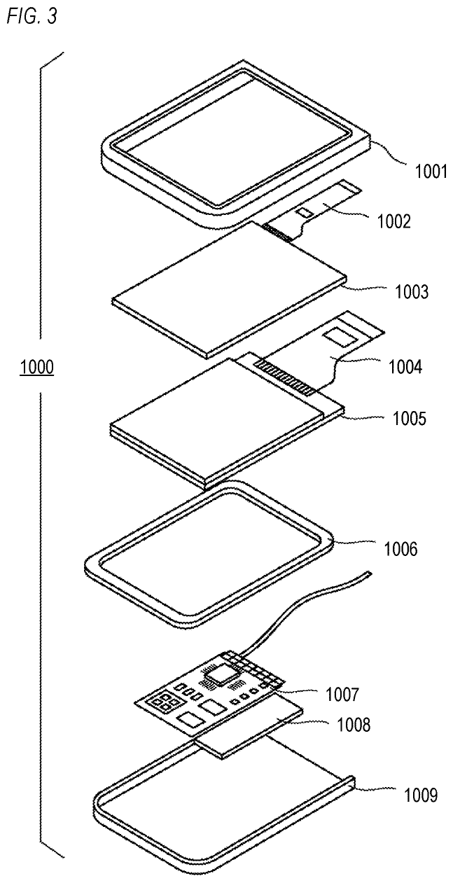

FIG. 3 is a schematic diagram illustrating a display device 1000 which is an example of a display device according to the second embodiment. The display device 1000 may include a touch panel 1003, a display panel 1005, a frame 1006, a circuit board 1007, and a battery 1008 between an upper cover 1001 and a lower cover 1009.

The display panel 1005 is a display unit including the semiconductor device according to the first embodiment, and performs display using light emitted from the semiconductor device. Flexible printed circuits FPCs 1002 and 1004 are connected to the touch panel 1003 and the display panel 1005. A control circuit including a transistor is printed on the circuit board 1007, and performs various controls such as control of the display panel 1005. The battery 1008 may not be provided unless the display device is a portable device, or may be provided at another position even if the display device is a portable device. The display device 1000 may include three types of color filters corresponding to red, green, and blue, respectively. The plurality of color filters may be disposed in a delta array.

The display device 1000 may be used for a display unit of a mobile terminal. At that time, the display device 1000 may have both a display function and an operation function. Examples of the mobile terminal include a mobile phone such as a smartphone, a tablet, and a head-mounted display.

The display device 1000 may be used for a display unit of an imaging apparatus including an optical unit having a plurality of lenses and an imaging element that receives light passing through the optical unit. The imaging apparatus may include a display unit that displays information (such as an image captured by the imaging element) acquired by the imaging element. Furthermore, the display unit may be a display unit exposed to the outside of the imaging apparatus or a display unit disposed in a finder. The imaging apparatus may be a digital camera, a digital video camera, and the like.

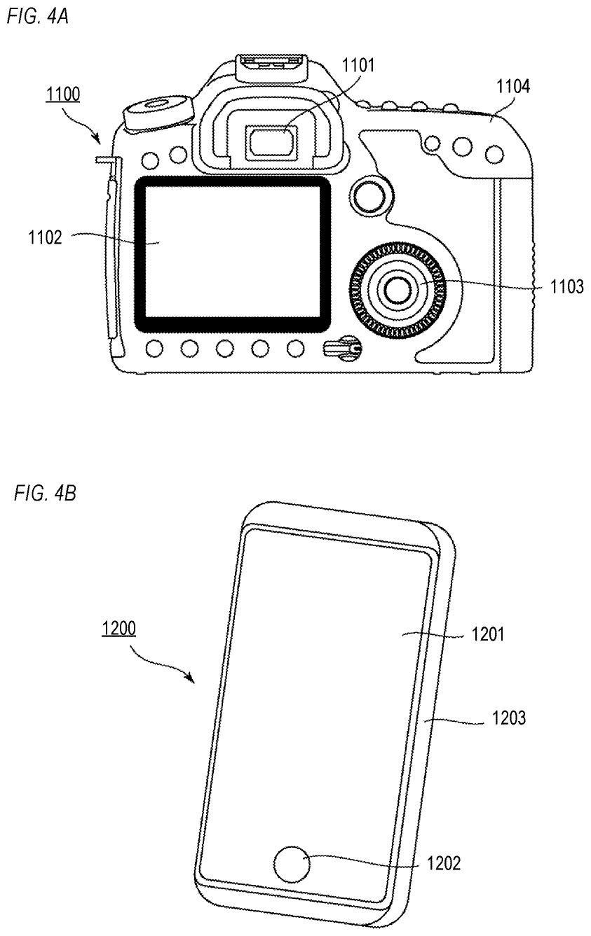

FIG. 4A is a schematic diagram illustrating an imaging apparatus 1100 which is an example of an imaging apparatus according to the second embodiment. The imaging apparatus 1100 may include a view finder 1101, a rear display 1102, an operation unit 1103, and a housing 1104. The view finder 1101 may include the display device (display device including the semiconductor device according to the first embodiment and performing display using light emitted from the semiconductor device) according to the second embodiment. In this case, the display device may display not only an image to be captured but also environmental information, an imaging instruction, and the like. The environmental information may be intensity of external light, a direction of the external light, a moving speed of a subject, a possibility that the subject is shielded by a shielding object, and the like. The rear display 1102 may also include the display device according to the second embodiment.

Since the timing suitable for imaging is a short time, it is better to display the information as soon as possible. Therefore, it is preferable to use a display device using an organic light emitting element having a high response speed. The display device using the organic light emitting element can be suitably used in a device requiring a display speed as compared with a liquid crystal display device or the like.

The imaging apparatus 1100 includes an optical unit (not illustrated). The optical unit includes a plurality of lenses and forms an image of light on an imaging element housed in the housing 1104. The plurality of lenses can adjust the focal point by adjusting their relative positions. This operation can also be performed automatically. The imaging apparatus 1100 may be referred to as a photoelectric conversion device. The photoelectric conversion device may include, as an imaging method, a method of detecting a difference from a previous image, a method of cutting out a part of a recorded image, and the like, instead of sequentially imaging.

FIG. 4B is a schematic diagram illustrating an electronic device 1200 which is an example of an electronic device according to the second embodiment. The electronic device 1200 includes a display unit 1201, an operation unit 1202, and a housing 1203. The display unit 1201 includes the semiconductor device according to the first embodiment, and performs display using light emitted from the semiconductor device. The electronic device 1200 may include, in the housing 1203, a circuit, a printed circuit board including the circuit, a battery, and a communication unit that communicates with the outside. The operation unit 1202 may be a button or a touch panel type reaction unit. The operation unit may be a biological recognition unit that recognizes a fingerprint and releases a lock or the like. The electronic device having the communication unit can also be referred to as a communication device. The electronic device may further include a camera function by including a lens and an imaging element. An image captured by the camera function is displayed on the display unit. Examples of the electronic device include a smartphone and a notebook computer.

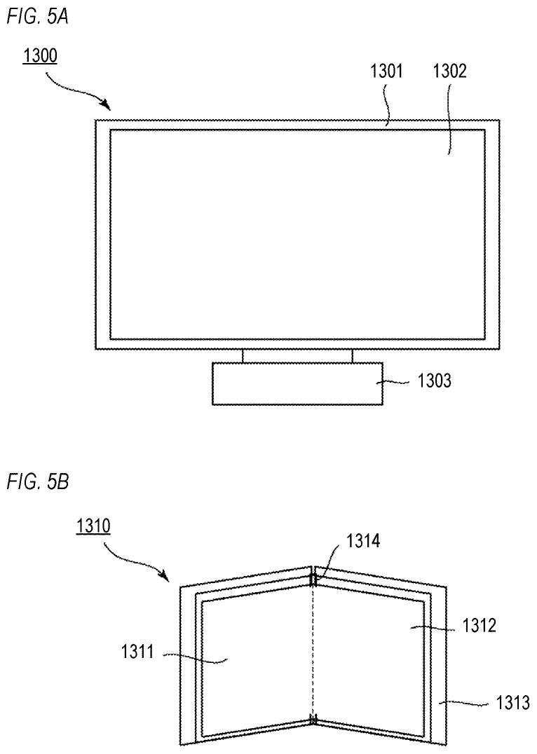

FIG. 5A is a schematic diagram illustrating a display device 1300 which is an example of the display device according to the second embodiment. The display device 1300 is a display device such as a television monitor or a PC monitor. The display device 1300 includes a frame 1301, a display unit 1302, and a base 1303 that supports the frame 1301 and the display unit 1302. The display unit 1302 includes the semiconductor device according to the first embodiment, and performs display using light emitted from the semiconductor device. The form of the base 1303 is not limited to the form of FIG. 5A. The lower side of the frame 1301 may also serve as the base 1303. The frame 1301 and the display unit 1302 may be bent. The radius of curvature may be 5000 mm or more and 6000 mm or less.

FIG. 5B is a schematic diagram illustrating a display device 1310 which is an example of the display device according to the second embodiment. The display device 1310 is a so-called foldable display device configured to be bendable. The display device 1310 includes a first display unit 1311, a second display unit 1312, a housing 1313, and a bending point 1314. Each of the first display unit 1311 and the second display unit 1312 includes the semiconductor device according to the first embodiment, and performs display using light emitted from the semiconductor device. The first display unit 1311 and the second display unit 1312 may be one display device without a joint. The first display unit 1311 and the second display unit 1312 can be divided at the bending point. The first display unit 1311 and the second display unit 1312 may display different images, or the first display unit 1311 and the second display unit 1312 may display one image.

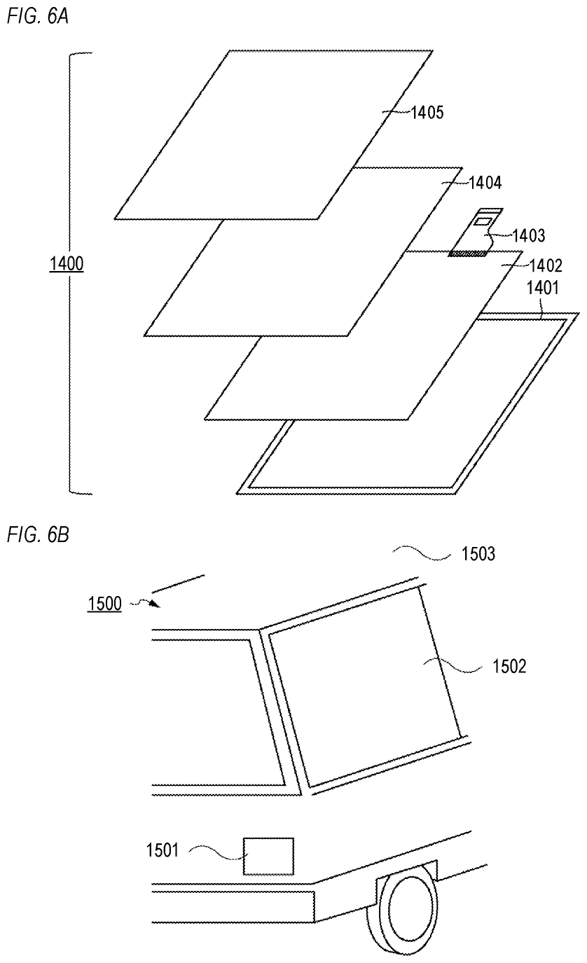

FIG. 6A is a schematic diagram illustrating an illumination device 1400 which is an example of an illumination device according to the second embodiment. The illumination device 1400 may include a housing 1401, a light source 1402, a circuit board 1403, an optical film 1404, and a light diffusion portion 1405. The light source 1402 includes the semiconductor device according to the first embodiment. The optical film 1404 may be a filter (optical filter) that improves the color rendering properties of the light source 1402. The light diffusion portion 1405 can effectively diffuse the light of the light source 1402 such as light up and deliver the light to a wide range. The optical film 1404 and the light diffusion portion 1405 may be provided on the light emission side of the illumination device 1400. If necessary, a cover may be provided on the outermost part.

The illumination device 1400 is, for example, a device that illuminates the interior. The illumination device 1400 may emit white light, neutral white light, and other colors (any color from blue to red). White is a color having a color temperature of 4200 K, and neutral white is a color having a color temperature of 5000 K. The illumination device 1400 may include a light control circuit that controls a light emission color of the illumination device 1400. The illumination device 1400 may include a power supply circuit connected to the light source 1402. The power supply circuit is a circuit that converts an AC voltage into a DC voltage. In addition, the illumination device 1400 may include a color filter. In addition, the illumination device 1400 may include a heat dissipation portion. The heat dissipation portion releases heat in the device to the outside of the device, and examples thereof include a metal having high specific heat and liquid silicon.

FIG. 6B is a schematic diagram illustrating an automobile 1500 which is an example of a moving body according to the second embodiment. The automobile 1500 may include a tail lamp 1501 which is an example of a lamp. The tail lamp 1501 is turned on in response to a brake operation or the like.

The tail lamp 1501 includes the semiconductor device according to the first embodiment. The tail lamp 1501 may include a protection member that protects the semiconductor device. The protection member has high strength to some extent, and is preferably made of polycarbonate or the like although the material is not limited as long as it is transparent. A furandicarboxylic acid derivative, an acrylonitrile derivative, or the like may be mixed with polycarbonate.

The automobile 1500 may have a vehicle body 1503 and a window 1502 attached to the vehicle body 1503. The window 1502 may be a transparent display as long as it is not a window for checking the front and rear of the automobile 1500. The transparent display may include the semiconductor device according to the first embodiment. In this case, a constituent material such as an electrode included in the semiconductor device is formed of a transparent member.

The moving body according to the second embodiment may be a ship, an aircraft, a drone, or the like. The moving body may include a machine body and a lamp provided on the machine body. The lamp may emit light for notifying the position of the machine body. The lamp includes the semiconductor device according to the first embodiment.

The display device (display device including the semiconductor device according to the first embodiment and performing display using light emitted from the semiconductor device) according to the second embodiment can also be applied to wearable devices such as smart glasses, HMDs, and smart contacts. The display device according to the second embodiment can also be applied to a system including a wearable device or the like. An imaging display device used as a wearable device or the like includes an imaging apparatus capable of photoelectrically converting visible light and a display device capable of emitting visible light.

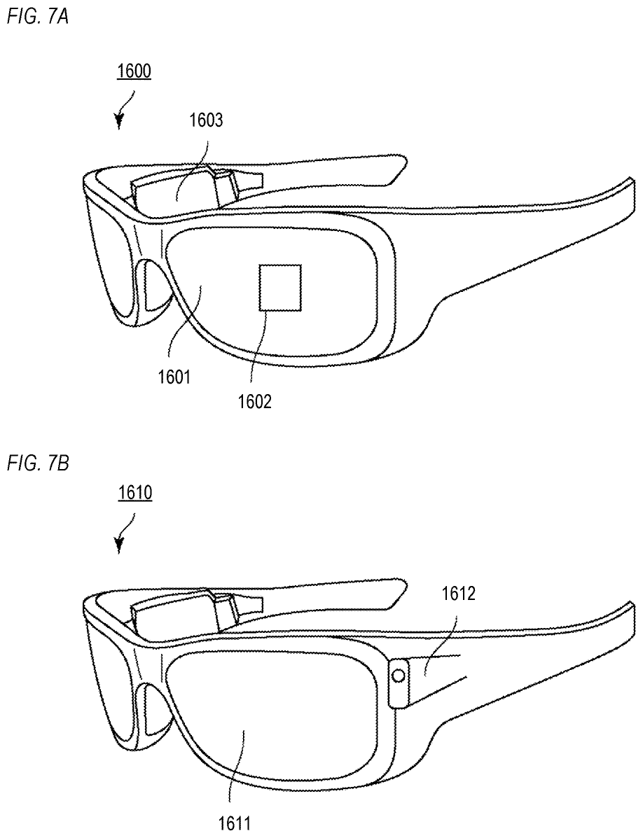

FIG. 7A is a schematic diagram illustrating glasses 1600 (smart glasses) as an example of a wearable device according to the second embodiment. An imaging apparatus 1602 such as a CMOS sensor or a SPAD is provided on the front surface side of a lens 1601 of the glasses 1600. The display device (display device including the semiconductor device according to the first embodiment and performing display using light emitted from the semiconductor device) according to the second embodiment is provided on the back surface side of the lens 1601.

The glasses 1600 further includes a control device 1603. The control device 1603 functions as a power supply that supplies power to the imaging apparatus 1602 and the display device. Furthermore, the control device 1603 controls operations of the imaging apparatus 1602 and the display device. The lens 1601 is formed with an optical system for condensing light on the imaging apparatus 1602.

FIG. 7B is a schematic diagram illustrating glasses 1610 (smart glasses) as an example of the wearable device according to the second embodiment. The glasses 1610 include a control device 1612, and an imaging apparatus corresponding to the imaging apparatus 1602 and the display device according to the second embodiment are mounted on the control device 1612. A lens 1611 is formed with the imaging apparatus in the control device 1612 and an optical system for projecting light emitted from the display device, and an image is projected on the lens 1611. The control device 1612 functions as a power supply that supplies power to the imaging apparatus and the display device, and controls operations of the imaging apparatus and the display device.

The control device may include a line-of-sight detector that detects the line of sight of a wearer of the glasses 1610. A line of sight may be detected using infrared light. An infrared light emitting unit emits infrared light to an eyeball of the user gazing at a display image. A captured image of the eyeball is obtained by an imaging unit including a light receiving element detecting reflected light from the eyeball of the emitted infrared light. By including a reduction unit that reduces light from the infrared light emitting unit to a display unit in plan view, deterioration in quality of an image projected from the display device onto the lens 1611 is reduced. The control device detects the line of sight of the user with respect to the display image from the captured image of the eyeball obtained by the imaging of the infrared light. Any known method can be applied to the line-of-sight detection using the captured image of the eyeball. As an example, a line-of-sight detection method based on a Purkinje image by reflection of irradiation light at the cornea can be used. More specifically, line-of-sight detection processing based on the pupillary and corneal reflex method is performed. A line-of-sight vector indicating the direction (rotation angle) of the eyeball is calculated based on the image of the pupil and the Purkinje image included in the captured image of the eyeball using the pupillary and corneal reflex method, whereby the line of sight of the user is detected.

Note that, in a case where display control is performed on the basis of visual recognition detection (line-of-sight detection), the semiconductor device according to the first embodiment can be preferably applied to smart glasses having an imaging apparatus that images the outside. The smart glasses can display the imaged external information in real time.

Note that the display device (display device including the semiconductor device according to the first embodiment and performing display using light emitted from the semiconductor device) according to the second embodiment may include an imaging apparatus having a light receiving element, and may control a display image on the basis of the line-of-sight information of a user from the imaging apparatus. Specifically, a first field-of-view area at which the user gazes and a second field-of-view area other than the first field-of-view area are determined on the basis of the line-of-sight information. The first field-of-view area and the second field-of-view area may be determined by the control device of the display device, or may be determined by an external control device and received by the display device. In a display area of the display device, the display resolution of the first field-of-view area may be controlled to be higher than the display resolution of the second field-of-view area. That is, the resolution of the second field-of-view area may be lower than that of the first field-of-view area.

In addition, the display area may have a first display area and a second display area different from the first display area, and an area having a high priority may be determined from the first display area and the second display area on the basis of the line-of-sight information. The first display area and the second display area may be determined by the control device of the display device, or may be determined by an external control device and received by the display device. The resolution of an area with high priority may be controlled to be higher than the resolution of an area other than the area with high priority. That is, the resolution of an area having a relatively low priority may be lowered.

Note that AI may be used to determine the first field-of-view area, the area with high priority, and the like. The AI may be a model configured to estimate the angle of a line of sight and the distance to a target object ahead of the line of sight from an image of an eyeball using an image of the eyeball and the direction actually viewed by the eyeball in the image as teacher data. An AI program may be included in the display device, the imaging apparatus, or an external device. In a case where the external device has the AI program, the determination is transmitted to the display device via communication.

As described above, by using the semiconductor device according to the first embodiment, various devices can perform stable display for a long time with favorable image quality.

Note that the functional units (configurations) of the various devices described in the second embodiment may or may not be individual hardware. The functions of two or more functional units may be implemented by common hardware. Each of a plurality of functions of one functional unit may be implemented by individual hardware. Two or more functions of one functional unit may be implemented by common hardware. In addition, each functional unit may or may not be implemented by hardware such as ASIC, FPGA, and DSP. For example, the device may include a processor and a memory (storage medium) storing a control program. Then, the functions of at least some functional units included in the device may be implemented by the processor reading and executing the control program from the memory.

According to the present invention, it is possible to provide a technique advantageous for stabilizing electric resistance at the time of connecting a semiconductor substrate and a semiconductor chip.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-217768, filed on Dec. 25, 2023, which is hereby incorporated by reference herein in its entirety.

What is claimed is:

1. A semiconductor device comprising:
a semiconductor substrate; and
a semiconductor chip connected to the semiconductor substrate via a plurality of terminals, wherein
the semiconductor substrate includes an effective element area and a peripheral area surrounding the effective element area,
the peripheral area is provided with an electrode portion to which the semiconductor chip is electrically joined,
a plurality of rows of terminals are disposed along a first direction of the semiconductor chip, and
terminals provided on a central portion of the semiconductor chip in the first direction, among the plurality of rows of terminals, are dummy terminals.

2. The semiconductor device according to claim 1, wherein X/10≤L≤X/4, where X is a width of the semiconductor chip in the first direction, and L is a width of an area occupied by the dummy terminals.

3. The semiconductor device according to claim 1, wherein each terminal in the dummy terminals is provided in a same pattern as each terminal in a part of the plurality of rows of terminals.

4. The semiconductor device according to claim 1, wherein an interval between two of the dummy terminals is wider than an interval between two of the terminals included in the plurality of rows of terminals.

5. The semiconductor device according to claim 1, wherein the semiconductor chip is bonded to the semiconductor substrate by flip chip bonding.

6. The semiconductor device according to claim 1, wherein the semiconductor chip is bonded to the semiconductor substrate with an anisotropic conductive film.

7. The semiconductor device according to claim 1, wherein the plurality of rows of terminals includes input terminals.

8. The semiconductor device according to claim 1, wherein the plurality of rows of terminals includes output terminals.

9. A display device comprising:
a display including the semiconductor device according to claim 1; and
a control circuit configured to control the display.

10. A photoelectric conversion device comprising:
an optical member;
an imaging element configured to receive light that has passed through the optical member; and
a display configured to display an image captured by the imaging element, wherein
the display includes the semiconductor device according to claim 1.

11. An electronic device comprising:
a display including the semiconductor device according to claim 1;
a housing in which the display is provided; and
a communication interface that is provided in the housing and communicates with an outside.
